(19) United States
(12) Patent Application Publication
(10) Pub. No.: US 2026/0017776 A1
(43) Pub. Date: Jan. 15, 2026

(54) PLACEMENT ALIGNMENT METHOD AND SYSTEM

(71) Applicant: UNIVERSAL INSTRUMENTS CORPORATION, Conklin, NY (US)

(72) Inventors: Koenraad Alexander GIESKES, Deposit, NY (US); John Edward DANEK, Vestal, NY (US); Philip Michael CASTORO, Endicott, NY (US); Michael Murray YINGLING, Binghamton, NY (US)

(21) Appl. No.: 18/880,392

(22) PCT Filed: Jun. 28, 2023
(86) PCT No.: PCT/US2023/026438

§ 371 Date: Dec. 31, 2024

Related U.S. Application Data
(60) Provisional application No. 63/357,942, filed on Jul. 1, 2022.
(60) Provisional application No. 63/414,275, filed on Oct. 7, 2022.

(51) Int. Cl. G06T 7/00; G06T 1/00; G06T 7/80; H04N 23/56

(52) U.S. Cl. CPC G06T 7/001; G06T 1/0014; G06T 7/80; H04N 23/56; G06T 2207/30141; G06T 2207/30148

(57) ABSTRACT

An electronic device placement system includes a spindle assembly having a positioning system configured to move between a picking location and a placement location, the spindle assembly including a spindle having a transparent spindle body and a vertical nozzle, an upward facing camera configured to image a bottom of an electronic device picked up by the nozzle of the spindle prior to a placement stroke of the electronic device, and a downward facing camera movable above the spindle during picking and placement of an electronic device by the spindle. The downward facing camera is configured to image outer edges of the electronic device during the placement stroke of the spindle through the transparent spindle body and to capture an image of a surface of a substrate prior to and/or during the placement stroke.

### RELATED MATTERS

This application is a national stage of PCT Application No. PCT/US2023/026438, having a filing date of Jun. 28, 2023, and entitled “PLACEMENT ALIGNMENT METHOD AND SYSTEM”, which claims priority to U.S. Provisional Patent Application 63/357,942, having a filing date of Jul. 1, 2022, and entitled “PLACEMENT ALIGNMENT METHOD AND SYSTEM,” and to U.S. Provisional Patent Application 63/414,275, having a filing date of Oct. 7, 2022 and entitled “PLACEMENT ALIGNMENT METHOD AND SYSTEM,” the disclosures of which are hereby incorporated by reference.

### TECHNICAL FIELD

This invention relates generally to placement of electronic devices, components and/or dies on a substrate, such as a wafer, printed circuit board, fan out panel, die or the like. More particularly, the present invention relates to placement methods and systems where an alignment of the features of the placed device to the target has improved accuracy or precision.

### BACKGROUND

There are typically four categories of known pick and place systems or assembly machines.

A first type of known assembly machine uses machine calibration to learn the position of the placement accuracy determining parts of the machine, such as the position of cameras to locate the device on the spindle of the placement head, the position of cameras to locate the substrate/destination of the part on the substrate and lastly the position of the spindles on the placement head with respect to these cameras. Using this information, the device can be placed with accuracies of about 10 microns. In general, this is a fast method to place the devices and speeds of thousands of components per hour are achieved.

The disadvantage of the first category of known machines is that the calibration values are not completely stable. Thermal effects, but also friction can impact the placement accuracy especially over time. In these machines, the placement is an open loop process and calibration needs to be monitored to get stable results.

A second type of known assembly machine uses two cameras to look down along the sides of the spindle at the back of the spindle tip. In such a machine, the spindle tip holds the device. Via holes in the tip, special marks on the substrate can be imaged by the two cameras that aid in the alignment of the part that is carried on the bottom of the spindle. Since the device held on the bottom of the spindle is imaged by an upward facing camera, the relation between the device and the holes in the spindle tip is known to the machine controller and thus almost without calibration the device can be accurately aligned while the spindle moves down with the device under guidance from the cameras that align the marks on the substrate with the holes in the spindle tip. This second type of known assembly machine is accurate to single micron level placement, but at speeds that are around one tenth of the speeds that require calibration (such as the first type of machine).

The second known assembly machine type monitors the back of the spindle while placing the part. The machine aligns the holes on the spindle tip with the marks on the substrate. The main disadvantage of this method is the fact that valuable surface area on the substrate needs to be sacrificed for these marks. This can lead to losing 10% to 50% of the substrate depending on the size of the substrate and the size of the marks. Additionally, the extra steps of the alignment process between part and holes in the spindle tip and between placement target and alignment marks may impact the placement accuracy.

A third type of known assembly machine includes a type of die placement equipment for wire bonding of the top of the die to the component substrate, which uses a camera on axis with a glass nozzle. In this type of assembly machine, the component top side may be imaged and aligned with the substrate with the use of a single camera that is positioned in a stationary manner over the substrate. This setup eliminates the need for a second upward facing camera that could inspect the bottom of the die to establish the position of the die with respect to the spindle. The setup also simplifies the calibration of the system.

This third type of known assembly machine does not align features on the bottom of the component to the substrate. Thus, the third type cannot be applicable to the required process of aligning micro connections on the bottom with corresponding connections on the substrate.

Lastly, there is a fourth type of known assembly machine can be used for the placement of high-powered LED component, where the position accuracy of the bottom of the component is not critical, but the position of the light emitting part of the top of the component needs to be accurately aligned. For these parts, a process called Top Alignment Placement is used, where first the component is inspected by a vision system camera from the top, before the component is picked up by the spindle. This enables the vision system to calculate the position of the light emitting area of the top with respect to the outline of the component. After the component is picked, the spindle carries the component to an upward looking device camera that images the bottom of the part. This enables a vision system to do the calculation of the position of the outline of the component with respect to the spindle. Subsequently the component can be placed on the substrate in such a way that the position accuracy of the light emitting area is optimized.

This fourth type of known assembly machine also does not align features on the bottom of the component to the substrate (like the third type, described above). Thus, the fourth type of known assembly machine enables alignment of the top of the component but does not align features on the bottom.

Thus, methods and systems where an alignment of the features of the placed device to the target has improved accuracy or precision, which do not need special features on the substrate, and which achieve sub-micron (i.e., better than 1 micron) precision, would be well received in the art.

### SUMMARY

According to one aspect, an electronic device placement system includes: a spindle assembly having a positioning system configured to move between a picking location and a placement location, the spindle assembly including a spindle having a transparent spindle body, the spindle including a nozzle mounted vertically to the transparent spindle body; an upward facing camera configured to image a bottom of an electronic device picked up by the nozzle of the spindle prior to a placement stroke of the electronic device; and a downward facing camera movable above the spindle during picking and placement of an electronic device by the spindle, wherein the downward facing camera is configured to image outer edges of the electronic device during the placement stroke of the spindle through the transparent spindle body, and wherein the downward facing camera is configured to capture an image of a surface of a substrate prior to and/or during the placement stroke.

According to another aspect, a method for placing an electronic device includes: moving a spindle assembly with a positioning system to a picking location, the spindle assembly including a spindle having a transparent spindle body, the spindle including a nozzle mounted vertically to the transparent spindle body; picking up an electronic component with the spindle; imaging, with an upward facing camera, a bottom of the electronic component picked up with the spindle prior to placement of the electronic component; moving the spindle with the electronic component to a placement location; imaging, with a downward facing camera, a surface of a substrate prior to and/or during the placement stroke; and imaging, with the downward facing camera that is movable above the spindle, outer edges of the electronic device during the placement stroke of the spindle through the transparent spindle body.

### BRIEF DESCRIPTION OF THE DRAWINGS

The above and further advantages of this invention may be better understood by referring to the following description in conjunction with the accompanying drawings, in which like reference numerals indicate like elements and features in the various figures. For clarity, not every element may be labeled in every figure. The drawings are not necessarily to scale, emphasis instead being placed upon illustrating the principles of the invention.

FIG. 1 depicts a top view of an electronic device placement system, according to one embodiment.

FIG. 2 depicts a side view of the electronic device placement system of FIG. 1, according to one embodiment.

FIG. 3A depicts a first downward facing camera image during or prior to picking, according to one embodiment.

FIG. 3B depicts a second downward facing camera image while a spindle is carrying a device, according to one embodiment.

FIG. 3C depicts a third downward facing camera image during active placement, according to one embodiment.

FIG. 4A depicts a schematic representation of a upward facing camera image of a bottom of a device including a bump pattern, according to one embodiment.

FIG. 4B depicts a step of processing the same image again for determining a center of the outline and determining an orientation angle of the outline, according to one embodiment.

FIG. 4C depicts a step of calculating the bump center with respect to the outline and corners, and further calculating the angle between the bump patterns with respect to the outline and corners, according to one embodiment.

FIG. 4D depicts a representation of a downward facing camera image of a top of a substrate, according to one embodiment.

FIG. 5A depicts a method of placing an electronic device, according to one embodiment.

FIG. 5B depicts a continuation of the method of FIG. 5A, according to one embodiment.

FIG. 6A depicts a side schematic view of an electronic device placement system including a downward facing camera and a spindle having a nozzle picking up an electronic device moved out of a vision path of the downward facing camera, according to one embodiment.

FIG. 6B depicts a side schematic view of the electronic device placement system of FIG. 6A including the downward facing camera and having the nozzle picking up the electronic device over a substrate, according to one embodiment.

FIG. 7 depicts a side schematic view of the electronic device placement system of FIGS. 6A and 6B including the downward facing camera and the spindle located over an upward facing camera, according to one embodiment.

FIG. 8 depicts another method of placing an electronic device, according to one embodiment.

### DETAILED DESCRIPTION

Reference in the specification to “one embodiment” or “an embodiment” means that a particular feature, structure or characteristic described in connection with the embodiment is included in at least one embodiment of the teaching. References to a particular embodiment within the specification do not necessarily all refer to the same embodiment.

The present teaching will now be described in more detail with reference to exemplary embodiments thereof as shown in the accompanying drawings. While the present teaching is described in conjunction with various embodiments and examples, it is not intended that the present teaching be limited to such embodiments. On the contrary, the present teaching encompasses various alternatives, modifications and equivalents, as will be appreciated by those of skill in the art. Those of ordinary skill having access to the teaching herein will recognize additional implementations, modifications and embodiments, as well as other fields of use, which are within the scope of the present disclosure as described herein.

The present disclosure enables placement of electronic devices, such as components, dies or the like, on a substrate or printed circuit board with an alignment of the features of device to the target on the substrate that is better than prior art equipment. For example, the present electronic device placements systems and methods described herein are capable of placing electronic devices with accuracies at or better than 1 micron.

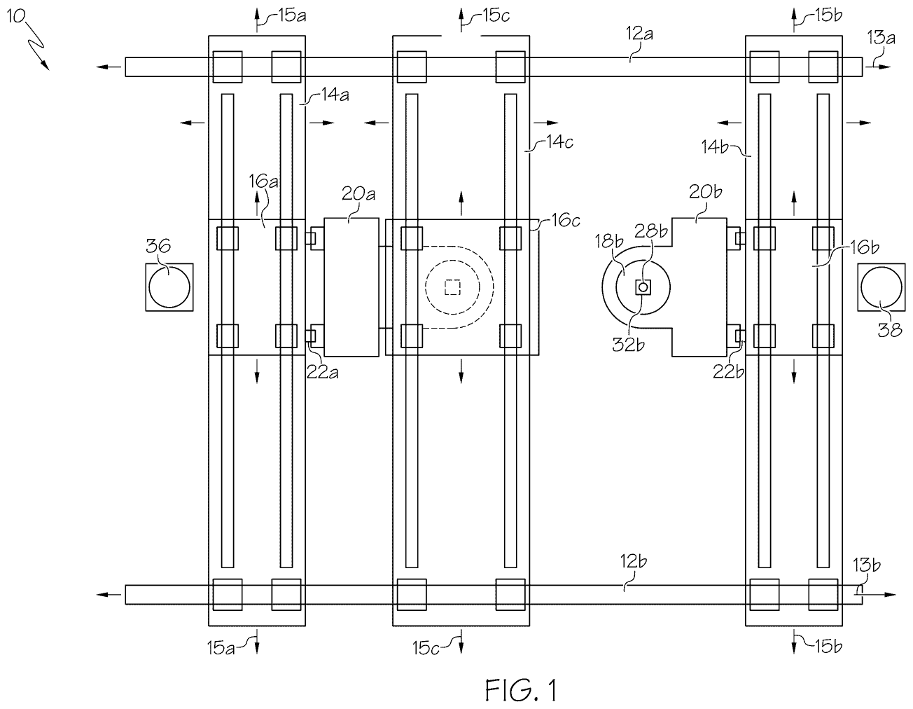

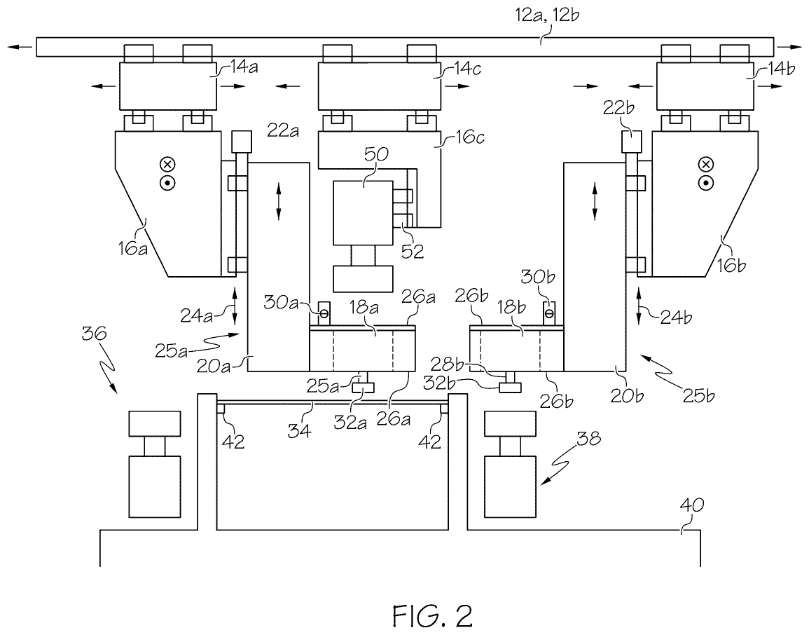

FIG. 1 depicts a top view of an electronic device placement system 10 while FIG. 2 depicts a side view of the electronic device placement system 10 of FIG. 1, according to one embodiment. As shown in FIGS. 1 and 2, the electronic device placement system 10 includes a positioning system that includes a pair of parallel linear bearings 12a, 12b disposed and extending in a Y-direction in Y-axes 13a, 13b, respectively. The positioning system further includes three beams extending between the pair of linear bearings 12a, 12b: a first beam 14a, a second beam 14b, and a third beam 14c.

The first beam 14a is movably coupled to the linear bearings 12a, 12b, and is disposed along a first X-axis 15a that is perpendicular to the Y-axes 13a, 13b. Likewise, the second beam 14b is movably coupled to the linear bearings 12a, 12b, and is disposed along a second X-axis 15b that is also perpendicular to the Y-axes 13a, 13b. Similarly, a third beam 14c is movably coupled to the linear bearings 12a, 12b and is disposed along a third X-axis 15c that is also perpendicular to the Y-axes 13a, 13b. Thus, the first, second and third beams 14a, 14b, 14c are parallel beams and disposed in a spaced apart manner along the Y-axes 13a, 13b between the pair of parallel linear bearings 12a, 12b. In particular, the third beam 14c is located between the first beam 14a and the second beam 14b. In other words, the first beam 14a is located on a first side of the electronic device placement system 10, while the second beam 14b is located on a second side of the electronic device placement system 10, with the third beam 14c located there between. The first, second and third beams 14a, 14b, 14c are each configured to independently move with respect to the linear bearings 12a, 12b in the Y-direction along the Y-axes 13a, 13b.

As shown, the positioning system includes a first carriage 16a that is movably coupled to the first beam 14a. The first carriage 16a is configured to move with respect to the first beam along the first X-axis 15a. Likewise, the positioning system further includes a second carriage 16b that is movably coupled to the second beam 14b. The second carriage 16a is configured to move with respect to the second beam 14b along the second X-axis 15b. Similarly, the positioning system includes a third carriage 16c that is movably coupled to the third beam 14c. The third carriage 16c is configured to move with respect to the third beam 14c along the third X-axis 15c.

The parallel linear bearings 12a, 12b and/or described beams 14a, 14b, 14c and/or the carriages 16a, 16b, 16c may include any type of positioning or bearing system configured to allow for movement of the spindle assemblies and/or downward facing camera system in both the X and Y directions along X and Y axes. The connection between these bearings, beams and carriages may take any form, such as wheels/rollers, sliding movement, or any other type of controllable precision bearing system.

A first spindle 18a of a first spindle assembly 25a is movably coupled to the first carriage 16a. In particular, the first spindle 18a is attached or otherwise coupled to a first piezo stage 20a which is attached or coupled to a first spindle assembly Z-drive 22a. In particular, the first spindle assembly Z-drive 22a is movably coupled to the first carriage 16a and is configured to move with respect to the first carriage 16a along a first Z-axis 24a. The first spindle assembly Z-drive 22a is configured to move the first spindle 18a along the first Z-axis 24a. The first piezo stage 20a is movably coupled between the first spindle assembly Z-drive 22a and the first spindle 20a. The first piezo stage 20a is configured to move the first spindle 18a with respect to the first spindle assembly Z-drive 22a to make fine positioning adjustments to the positioning of the first spindle 18a.

Like the first spindle 18a, a second spindle 18b of a second spindle assembly 25b is movably coupled to the second carriage 16b. In particular, the second spindle 18b is attached or otherwise coupled to a second piezo stage 20b which is attached or coupled to a second spindle assembly Z-drive 22b. In particular, the second spindle assembly Z-drive 22b is movably coupled to the second carriage 16b and is configured to move with respect to the second carriage 16b along a second Z-axis 24b. The second spindle assembly Z-drive 22b is configured to move the second spindle 18b along the second Z-axis 24b. The second piezo stage 20b is movably coupled between the second spindle assembly Z-drive 22b and the second spindle 20b. The second piezo stage 20b is configured to move the second spindle 18b with respect to the second spindle assembly Z-drive 22b to make fine positioning adjustments to the positioning of the second spindle 18b.

The first and second spindles 18a, 18b may be spindle assemblies which include a transparent first spindle body 19a, and a second transparent spindle body 19b, respectively. The transparent first and second spindle bodies 19a, 19b may each include a pair of glass plates 26a, 26b, one above and one below the structure of the spindles 18a, 18b. Instead of a glass plates, other transparent materials may be used especially if different wavelength light may be used for illumination, like infrared light or X-ray. Further, the primary structure of the spindles 18a, 18b may be made of transparent material. The first and second spindles 18a, 18b may include a vertically aligned nozzle 28a, 28b, respectively. The spindle nozzles 28a, 28b may be made of a transparent material as well in some embodiments. Still further, the first and second spindles 18a, 18b may each be configured to provide air distribution to the spindle nozzles 28a, 28b, respectively, in order to create a vacuum suction and/or air emission from the nozzles 28a, 28b. The spindles 18a, 18b may further contain a theta drive 30a, 30b, respectively, to rotate the glass plates enabling pick up and placement at different angles.

As shown, the nozzles 28a, 28b have each picked up a respective electronic device 32a, 32b, such as a component, die or the like. The combination of the positioning system of the linear bearings 12a, 12b, the beams 14a, 14b, and the Z-drives 22a, 22b, and the theta drives 30a, 30b enable the electronic device placement system 10 to pick up an electronic device 32a, 32b, and move the electronic device 32a, 32b during all the large distances by the positioning system in the X, Y, Z axes and the theta (rotational) axis. Once the first and second spindles 18a, 18b, with a picked electronic device 32a, 32b attached or otherwise on the nozzles 28a, 28b, the electronic devices 32a, 32b may be transported from a picking location, such as a feeder area and/or feeder bank (not shown), to a device imaging location and/or a placement location over a substrate 34 or other target, as described herein below.

In the embodiment shown, the electronic device placement system 10 further includes a first upward facing camera 36 facing upward that is configured to image a bottom of an electronic device. In particular, the first upward facing camera 36 may be configured to image an electronic device picked up by the first spindle 18a, such as the first electronic device 32a. The imaging of the first upward facing camera 36 occurs prior to the placement stroke of the first spindle 18a for placing the first electronic device 32a.

Like the first upward facing camera 36, the electronic device placement system 10 further includes a second upward facing camera 38 facing upward and configured to image a bottom an electronic device. In particular, the second upward facing camera 38 may be configured to image an electronic device picked up by the second spindle 18b, such as the second electronic device 32b. The imaging of the second upward facing camera 38 occurs prior to the placement stroke of the second spindle 18b for placing the second electronic device 32b.

The electronic device placement system 10 further includes a machine base 40 located under the positioning system, the linear bearings 12a, 12b, the beams 14a, 14b, 14c and the like. The positioning system may be operably attached or connected to the machine base 40 of the electronic device placement system 10. The machine base 40 includes a substrate holder system 42 for holding the substrate 34, upon which the first and second electronic devices 32a, 32b are placeable during a placement stroke of the respective first and second spindles 18a, 18b. The first upward facing camera 36 facing upward is located on a first side of the substrate holder system 42 and the second upward facing camera 38 facing upward is located on a second side of the substrate holder. In other words, the first side of the substrate holder 42 is proximate a first end of the linear bearing(s) 12a, 12b, and the second side of the substrate holder 42 is proximate a second (opposite) end of the linear bearings 12a, 12b.

The electronic device placement system 10 further includes a downward facing camera 50 coupled to the third carriage 16c. While the embodiment shown in FIGS. 1 and 2 includes a single downward facing camera 50, it should be understood that embodiments are contemplated where more than one downward facing camera are deployed. For example, a downward facing camera may be deployed for each individual spindle assembly. As shown in FIGS. 1-2, the downward facing camera 50 is movable above the first spindle 18a during placement of a first electronic device by the first spindle 18a, such as the first electronic device 32a. The downward facing camera 50 may be positionable roughly located over the target (e.g., within 100 micron) in the X, Y, Z axes and the rotational axis, and the large axes X, Y and Z and theta of the positioning system of the beams 14a, 14b, 14c, carriages, 16a, 16b, 16c, and Z-Drives 22a, 22b, 52 come to a complete stop.

Once in position, the downward facing camera 50 is configured to image outer edges of picked electronic devices during a placement stroke of the first spindle 18a through the transparent first spindle body (as described above). Likewise, the downward facing camera 50 is movable above the second spindle 18b during placement of a second electronic device by the second spindle 18b, such as the second device 32b. In order for this to occur, the first beam 14a may be moved along the linear bearings 12a, 12b away from the substrate 34 and toward the upward facing camera 36 and/or a feeder bank or picking location. Then, the second beam 14b may be moved above or over the substrate 34. Here, the downward facing camera 50 may thereby be configured to image outer edges of picked electronic devices during a placement stroke of the second spindle 18b through the transparent second spindle body (as described above). The downward facing camera 50 is also capable of, or configured to, being moved in the vertical Z-direction, via a camera Z-drive 52 to enable focusing on the substrate, but also on the device when the downward facing camera 50 is suspended above the substrate 34.

Thus, the first and second beams 14a, 14b (i.e. placement beams) of the system 10 carries the spindles 18a, 18b, respectively, and can move each spindle 18a, 18b independent of the third beam 14c (i.e. the camera beam) in the X, Y, and Z axes as long as the first and second beams 14a, 14b stay on respective sides of the third beam 14c. In other words, the first, second and third beams 14a, 14b, 14c may not be capable of passing each other in the Y-direction along the linear bearings 12a, 12b.

In order to provide room for the downward facing camera 50, the spindle assemblies may be extended from the respective placement head-beam (i.e. the first and second beams 14a, 14b) in the direction of the camera beam (i.e. the third beam 14c) such that it can position the spindles 18a, 18b underneath the downward facing camera 50, when the beams get close to each other. For example, the first spindle 18a is positionable directly under the downward facing camera 50 when the first beam 14a is proximate the third beam 14c, and the second spindle 18b is positionable directly under the downward facing camera 50 when the second beam 14b is proximate the third beam 14c.

The extended part of each of the spindles 18a, 18b carries the nozzle 28a, 28b mounted vertically between the centers of the two horizontal glass plates 18a, 18b to allow the downward facing camera 50 on the third beam 14c to be positioned above the glass plates to image the outer edges of a picked device during the actual placement stroke and actively align this edge with the target on the substrate 34.

The first and second piezo stages 20a, 20b may be each configured to make fine adjustments to the positioning of the first and second spindles 18a, 18b, respectively, in 6 axial directions, including an X-axial direction, a Y-axial direction, a Z-axial direction, a theta rotational axial direction, an alpha rotational axial direction, and a beta rotational axial direction. The X-axial direction may be parallel to the X-axes 15a, 15b, 15c, the Y-axial direction may be parallel to the Y-axes 13a, 13b, and the Z-axial direction may be parallel to the Z-axes 24a, 24b. The alpha rotational direction may be a rotation which is about an axis that is parallel to the X-axes 15a, 15b, 15c, the beta rotational direction may be a rotation which is about an axis that is parallel to the Y-axes 13a, 13b, and the theta rotational direction may be a rotation which is about an axis that is parallel to the Z-axes 24a, 24b.

For the final adjustments a 6 degree of freedom Piezo actuator driven stage, that is mounted between the PH-beam carriage's Z-drive and the spindle assembly, is able to make precision position adjustments based on the spindle-camera information of the difference between target position and actual position of the device, while moving in small steps slowly to the substrate. The Piezo Stage is able to make sub-micron adjustments of the device on the nozzle tip with respect to the spindle-camera and the substrate in the X, Y, and Z directions, but also in theta, alpha and beta angles. The angular adjustments are needed for theta to be more accurate than the traditional theta servo drive. The adjustment for alpha and beta enables an improved coplanar touchdown of the device on the substrate, preventing crushing of corner interconnect features on the device or the substrate.

As described above, in exemplary embodiments herein, the electronic device placement systems and methods utilize one or more Cartesian positioning system beams in an electronic device placement assembly machine or system. The beams disclosed herein are configured to move along the same linear bearings in a Y-direction, and enable carriages to move along each beam in the X-direction. The camera beam carries the spindle-camera looking down vertically. This camera can image the substrate and, using a vision system, can determine position of the interconnect features on the substrate, which is the target for the device to be placed.

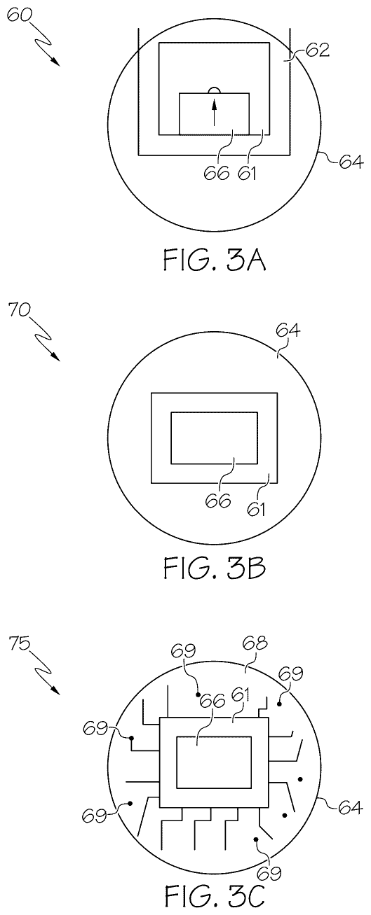

FIG. 3A depicts a first downward facing camera image 60 during or prior to picking, according to one embodiment. As shown, the image includes an electronic device 61 located on a device feeder 62. It should be understood that the electronic device 61 may be the same or similar to the electronic devices 32a, 32b described herein above. The view shows a glass spindle 64, such as one of the spindles 18a, 18b described herein above. Through the glass spindle 64, the device feeder 62 is visible and imageable, as well as the electronic device 61. A nozzle 66 is depicted in the middle of the glass spindle 64. The nozzle 66 is located over the electronic device 61 for picking, but in the position shown, and from the image viewed by the downward facing camera, such as the downward facing camera 50 described herein above, the nozzle 66 needs to be moved upward in order to be centered over the electronic device 61.

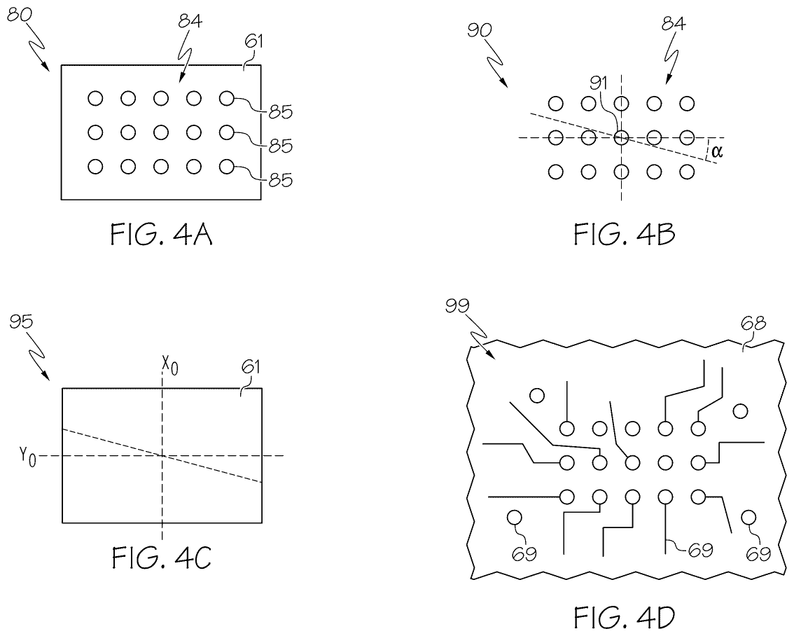

FIG. 3B depicts a second downward facing camera image 70 while the glass spindle 64 is carrying the electronic device 61, according to one embodiment. In particular, the second spindle camera image 70 may be taken after picking up the electronic device 61 from the device feeder 62 shown in FIG. 3A, and/or while the glass spindle 64 is taking the electronic device 61 to the placement location or substrate. In this image, the spindle camera may capture an outline of the electronic device 61, including the corners of the electronic device 61. In some embodiments, this downward facing camera image 70 may be taken by a downward facing camera concurrently or simultaneously to an upward facing image being taken by an upward facing camera of a bottom of the electronic device (as shown in FIG. 4A).

FIG. 3C depicts a third downward facing camera image 75 during active placement, or during a placement stroke of the spindle 64, according to one embodiment. The third downward facing camera image 75 shows the glass spindle 64 over a placement location on a substrate 68 during placement. The substrate includes features 69 which may be imaged by the downward facing camera in order to facilitate determining a precise placement location. In particular, the imaging, such as the third downward facing camera image 75 may be used to align the outline and corners of the electronic device 61 to the features on the substrate 68.

FIG. 4A depicts a schematic representation of a camera image 80 of a bottom of the device 61 including a bump pattern 84 having a plurality of bumps 85, according to one embodiment. As described above, this camera image 80 may be taken concurrently or simultaneously to the downward facing camera image 70 of FIG. 3B. The camera image 80 may be taken by an upward facing camera, which may be located proximate a placement location, as shown in FIG. 2. Thus, the spindle may move a picked electronic device over the upward facing camera for the capturing of the camera image 80. The camera image 80 may be used by the placement system in order to process the bump pattern, find the center, find the orientation angle, and any other image processing desired based on the bottom of the electronic device 61.

FIG. 4B depicts a step 90 of processing the same image again for determining a center 91 of the outline and determining an orientation angle a of the outline and the corners, according to one embodiment. The outline may be located in a plane defined by X and Y axes. FIG. 4C depicts a step 95 of calculating the bump center with respect to the outline and corners of the device 61, and further calculating the angle a between the bump patterns with respect to the outline and corners, according to one embodiment.

FIG. 4D depicts a representation of a downward facing camera image 99 of a top of the substrate 68, according to one embodiment. The downward facing camera image 99 may be taken by the downward facing camera. During the placement process, the downward facing camera may process the bump pattern and orientation angle as shown in FIGS. 4B and 4C. The downward facing camera image 99 may then be processed to find the substrate features 69 prior to bringing the electronic device 61 to the placement location. The features on the substrate may be traces, vias or fiducial marks, but they may also be the actual substrate interconnect features that may be aligned with the interconnect features on the bottom of the device 61.

With the above imaging, the center 91 of the bump pattern 84 may be calculated with respect to the chosen features 69 on the substrate 68. Further, the angle a of the bump pattern 84 may also be calculated with respect to the features 69 on the substrate 68. With this information and these images, the electronic component may be accurately placed with high levels of precision.

In operation, the sequence of events of the electronic device placement system 10 may be as follows. Initially, the first spindle assembly (i.e., the first carriage 16a, the first Z-drive 22a, the first piezo stage 20a, the first spindle 18a, the glass plates 26a, and the first nozzle 28a) may be moved by the first beam 14a in the X, Y, and Z directions and in theta (rotational direction) to the device feeder location for electronic device pick up. The placement head-positioning system is expected to be accurate enough for this pickup process without imaging, but the downward facing camera 50 may also be used for this move to ensure that the nozzle 28a picks the first electronic device 32a such that there is an edge of the first electronic device 28a that remains visible to the downward facing camera 50 beyond the entire perimeter of the tip of the nozzle 28a. Next, the placement head-positioning system moves the spindle assembly to the upward looking upward facing camera 36 which is configured to image interconnect features of the bottom of the electronic device 32a in such a way that the exact position of these features in the X, Y and theta is found. Concurrently or simultaneously, imaging may also be conducted by the downward facing camera 50 of the top side of the first electronic device 28a through the transparent spindle. Subsequently, the placement head-positioning system processes the same image for the exact position of the edge of the device and calculates the relation between the position of the edge and the position of the interconnect features in the X, Y and theta.

It should be understood that, although not shown, the electronic device placement system 10 may include a control and/or imaging system. The control and/or imaging system may include one or more computer processors and/or memory systems and/or data storage systems, computer system bus, and the like. The electronic device placement system 10 may include wireless components or alternatively may be completely wired and internal to the electronic device placement system 10. In some embodiments, the various cameras 36, 38, 50 may include their own localized processing systems, which may be all interconnected via the electronic device placement system 10. Whatever the embodiment, the computer processors and this control and/or imaging system may be configured to perform the imaging and control the various movements of the placement head-positioning system for both picking and placing, as described herein.

During the imaging process (e.g., conducted by the control system) of the upward facing camera 36, the downward facing camera 50 may be positioned above the target area of the substrate 34. The downward facing camera 50 may then image this target area and calculate the position of the interconnect features of the substrate 34, and additionally the features in the same image that will be visible also when the nozzle 28a with the electronic device 32a is covering the substrate's interconnect features. The vision system of the downward facing camera 50 may then calculate the position in X, Y and theta of the interconnect features during the placement move. Next, the placement head-positioning system moves the first spindle 18a to the placement site on the substrate 34 to within a relatively close position to the eventual exact placement location—e.g., about 100 micron for X, Y and around 2 mm for Z and around 0.1 degree for theta. By imaging the edge of the electronic device 28a, the vision system of the downward facing camera 50 may calculate the position of the interconnect features on the bottom side of the electronic device 32a by using the earlier collected information provided by the upward facing camera 36 about the relation between the edge and the interconnect features.

If a larger correction (i.e., greater than 100 microns for X, Y and around 2 mm for Z and around 0.1 degree for theta) is required, the placement head-positioning system may make a move via movement of the first beam 14a, the first carriage 16a, the Z-drive 22a, and the theta drive 30a. Alternatively, if distance between the position of the interconnect features and the target is within a relatively close position (i.e., greater than 100 microns for X, Y and around 2 mm for Z and around 0.1 degree for theta), then the piezo stage 20a may be used and the electronic device 32a may be thereby centered with the required precision to the target on the substrate 34.

Next, the nozzle 28a is lowered by the Z-drive 22a until, without touching, the device edge is in focus of the downward facing camera 50 at the same time as the substrate features are in focus. At this time a final correction may be needed by the piezo stage 20a to achieve nanometer alignment in X, Y, Theta. Finally, the placement is executed by the Z-drive 22a, and/or the Z-drive of the piezo stage 20a. Furthermore, the sensors in the piezo stage 20a can at this time be used as sensors to register the contact force. The alpha and beta rotational axes from the piezo stage 20a may further be used in combination with a set of laser sensors to adjust to the substrate surface angle in a way that all bumps make contact to their targets at the same time.

Once this placement process has completed, the first spindle assembly may be returned, via the placement head-positioning system, to the electronic component feeder bank for picking the next component. While this occurs, the same process described hereinabove may be conducted with the second spindle assembly (i.e., the second carriage 16b, the second Z-drive 22b, the second piezo stage 20b, the second spindle 18b, the glass plates 26b, and the second nozzle 28b), along with the downward facing camera 50 and the upward facing camera 38.

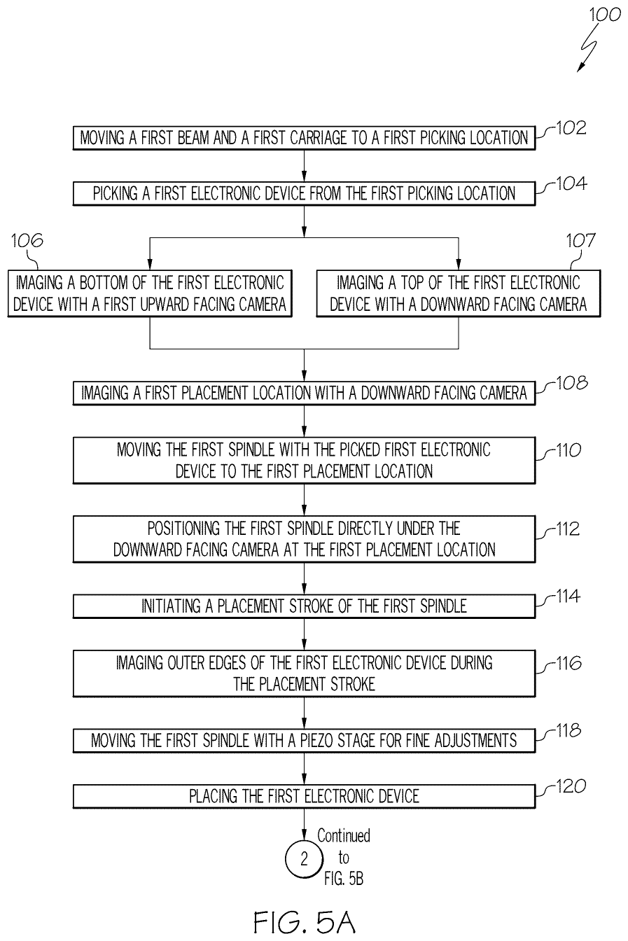

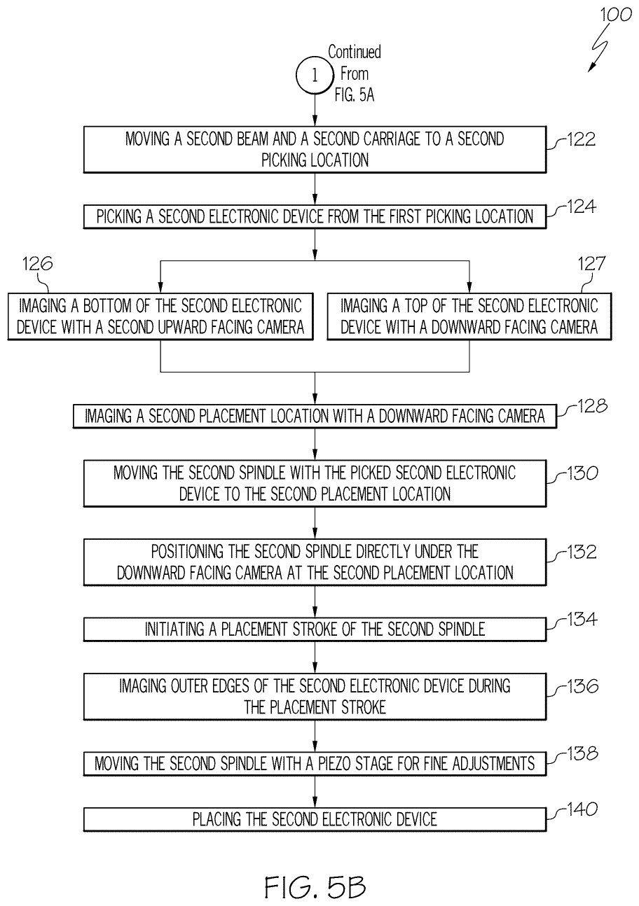

FIG. 5A depicts a method 100 of placing an electronic device, such as one or both of the electronic devices 32a, 32b, according to one embodiment. The method 100 includes a first step 102 of moving a first beam and a first carriage. This step may include moving a first beam with respect to at least one linear bearing along a Y-axis. The first beam may be disposed along a first X-axis that is perpendicular to the Y-axis, and the first beam may be movably coupled to the at least one linear bearing. This step may further include moving a first carriage with respect to the first beam along the first X-axis. The first carriage may be movably coupled to the first beam.

The method 100 may include a next step 104 of picking, by a first spindle that is movably coupled to the first carriage, a first electronic device at a first picking location. The first spindle may include a transparent first spindle body, as described herein above.

The method 100 may then include a step 106 of moving the first spindle with the picked first electronic device to a first imaging location by moving one or more of the first beam along the Y-axis and the first carriage along the X-axis, and imaging, by a first upward facing camera, a bottom of the first electronic device at the first imaging location. Concurrent to the step 106 of imaging the bottom of the first electronic device by the upward facing camera, the method 100 may include a simultaneous step 107 of imaging a top of the first electronic device with the downward facing camera. This concurrent imaging may provide a high accuracy relation between the top edge imaged in step 107 of the first electronic device and the bump pattern imaged during the step 106 of the bottom of the first electronic device.

The method may include a step 108 of imaging, with the downward facing camera, the first placement location. It should be understood that step 108 may occur prior to the moving the first spindle with the picked first electronic device to the first placement location.

The method 100 may then include a step 110 of moving the first spindle with the picked first electronic device to the first placement location by moving the first beam along the Y-axis. The method 100 may then include a step 112 of positioning the first spindle directly under the downward facing camera at the first placement location (i.e., when the first beam is proximate the third beam). This step 112 may include moving at least one of a third beam and the first beam such that the third beam is proximate the first beam.

The method 100 may then include a step 114 of initiating a placement stroke of the first spindle to begin placing the picked first electronic device on a substrate at the first placement location. A step 116 then includes imaging, by the downward facing camera, outer edges of the first electronic device during the placement stroke of the first spindle through the transparent first spindle body.

The method 100 may then include a step 118 of moving the first spindle with respect to the first spindle assembly Z-drive with a first piezo stage to make fine adjustments to positioning of the first spindle. Then method 100 may then include a step 120 of placing the first electronic device on the substrate at the first placement location.

The method 100 further includes additional steps shown in FIG. 5B. While the steps shown in FIG. 5B are shown subsequent to the steps shown in FIG. 5A, some of the steps may occur before all of the steps are completed in FIG. 5A, and may be performed concurrent to steps shown in FIG. 5A.

FIG. 5BA depicts a continuation of the method 100 of placing an electronic device, such as one or both of the electronic devices 32a, 32b, according to one embodiment. The method 100 includes a next step 122 of moving a second beam and a second carriage. This step may include moving a second beam with respect to at least one linear bearing along a Y-axis. The second beam may be disposed along a first X-axis that is perpendicular to the Y-axis, and the second beam may be movably coupled to the at least one linear bearing. This step may further include moving a second carriage with respect to the second beam along the first X-axis. The second carriage may be movably coupled to the second beam.

The method 100 may include a next step 124 of picking, by a second spindle that is movably coupled to the second carriage, a second electronic device at a second picking location. The second spindle may include a transparent first spindle body, as described herein above.

The method 100 may then include a step 126 of moving the second spindle with the picked second electronic device to a second imaging location by moving one or more of the second beam along the Y-axis and the second carriage along the X-axis, and imaging, by a second upward facing camera, a bottom of the second electronic device at the second imaging location. Concurrent to the step 126 of imaging the bottom of the second electronic device by the upward facing camera, the method 100 may include a simultaneous step 127 of imaging a top of the second electronic device with the downward facing camera. This concurrent imaging may provide a high accuracy relation between the top edge imaged in step 127 of the second electronic device and the bump pattern imaged during the step 126 of the bottom of the second electronic device.

While step 126 is occurring, the method may include a step 128 of imaging, with the downward facing camera, the second placement location. It should be understood that step 128 may occur prior to the moving the second spindle with the picked second electronic device to the second placement location.

The method 100 may then include a step 130 of moving the second spindle with the picked second electronic device to the second placement location by moving the second beam along the Y-axis. The method 100 may then include a step 132 of positioning the second spindle directly under the downward facing camera at the second placement location (i.e., when the second beam is proximate the third beam). This step 132 may include moving at least one of the third beam and the second beam such that the third beam is proximate the second beam.

The method 100 may then include a step 134 of initiating a placement stroke of the second spindle to begin placing the picked second electronic device on the substrate at the second placement location. A step 136 then includes imaging, by the downward facing camera, outer edges of the second electronic device during the placement stroke of the second spindle through the transparent second spindle body.

The method 100 may then include a step 138 of moving the second spindle with respect to the second spindle assembly Z-drive with a second piezo stage to make fine adjustments to positioning of the second spindle. Then method 100 may then include a step 140 of placing the second electronic device on the substrate at the second placement location. The method 100 may continue in this manner, alternating between picking and placing by each of the first and second spindles.

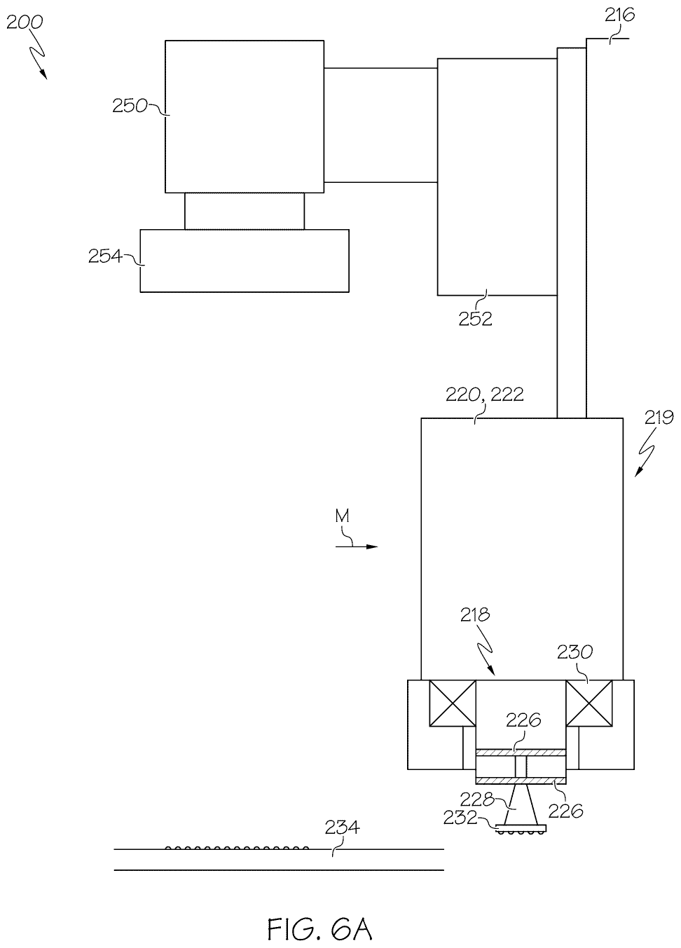

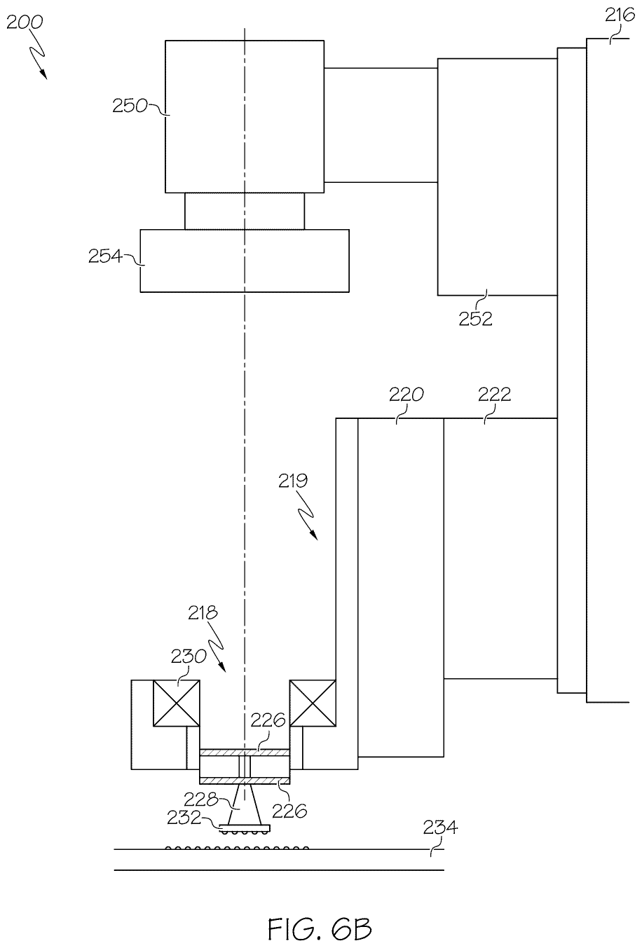

FIG. 6A depicts a side schematic view of an electronic device placement system 200 including a downward facing camera 250 and a spindle 218 of a spindle assembly 219 having a nozzle 228 picking up an electronic device 228 moved out of a vision path of the downward facing camera 250, according to one embodiment. FIG. 6B depicts a side schematic view of the electronic device placement system 200 including the downward facing camera 250 and having the nozzle 228 picking up the electronic device 228 over a substrate 234, according to one embodiment.

While not shown, the electronic device placement system 200 may include a positioning system having a pair of linear bearings, such as the linear bearings 12a, 12b, and at least one beam, such as one of the beams 14a, 14b, 14c. Upon this beam, a carriage 216 is shown, upon which both the downward facing camera 250 and the spindle 218 is movably coupled. Thus, the beam in this embodiment may movably coupled to the at least one bearing disposed along an X-axis that is perpendicular to the Y-axis. The beam may be configured to move with respect to the at least one linear bearing along the Y-axis to effectuate X and Y directional movement. The carriage 216 may be movably coupled to the beam and may be configured to move with respect to the beam along the X-axis.

The electronic device placement system 200 includes a spindle assembly Z-drive 222 movably coupled to the carriage 216 that is configured to move with respect to the carriage along a Z-axis that is vertical and perpendicular to each of the X-axis and the Y-axis. Similarly, a spindle 218 is coupled to the spindle assembly Z-drive 222. The spindle may be the same or similar to the spindles 18a, 18b described hereinabove. As shown, the spindle 218 includes a nozzle 228 mounted vertically to a transparent spindle body. The transparent spindle body includes two glass plates 226. As shown, the spindle 218 includes a theta drive 230 to rotate the spindle 218 and the nozzle 228.

While not shown, the electronic device placement system 200 may include a camera facing upward and configured to image a bottom of an electronic device 232, like one of the upward facing cameras 36, 38 described hereinabove. The electronic device placement system 200 may only include a single upward facing camera in this single spindle embodiment. The device camera may be configured to image the electronic device 232 picked up by the nozzle 228 of the spindle 218 prior to a placement stroke of the electronic device 232.

The electronic device placement system 200 includes a downward facing camera 250 movable above the spindle 218 during placement of the electronic device 232 by the spindle 218, as shown in FIG. 6B. The downward facing camera 250 is configured to image outer edges of the electronic device 232 during the placement stroke of the spindle 218 through the transparent spindle body. The downward facing camera 250 may include a lens and/or lighting system 254 to facilitate proper imaging. The downward facing camera 250 may include a camera Z-drive 252 movably coupled to the carriage 216 configured to move with respect to the carriage in the Z-axis. Thus, the downward facing camera 250 and the spindle 218 may be movably coupled to the same carriage 216 in the embodiment shown. However, the downward facing camera 250 may be independently movable with respect to the carriage 216 in the Z-axis from the spindle 218. Thus, each of the spindle 218 and the downward facing camera 250 include dedicated individual Z-drives 222, 252 for independent motion.

As shown in FIG. 6A, the spindle 218 may be configured to move out from a vision path of the downward facing camera 250 along a movement path M when the spindle camera is pointed at a placement location. In the embodiment shown, the spindle 218 may be configured to hingedly rotatably about the carriage 216. However, in other embodiments, the spindle 218 may be movable along a spindle linear bearing (not shown) with respect to the carriage 216 to move out from below the downward facing camera 250 and allow for direct imaging by the downward facing camera 250 of the substrate 234. The spindle 218 may be movable with respect to the downward facing camera 250 by at least one degree of freedom. Alternatively, spindle 218 may be movable with respect to the downward facing camera 250 by at least two degrees of freedom (i.e., vertical independent motion, and horizontal independent motion). Further, while not shown, it should be understood that the electronic device placement system 200 includes a machine frame and substrate holder system, such as the machine frame 40 and the substrate holder system 42 described herein above.

The electronic device placement system 200 further includes a piezo stage 220 movably coupled between the spindle assembly Z-drive 222 and the spindle 218. The piezo stage 220 may be configured to move the spindle 218 with respect to the spindle assembly Z-drive 222 to make fine positioning adjustments to the positioning of the spindle 218. The piezo stage is configured to make fine adjustments to the positioning of the spindle in 6 axial directions, including an X-axial direction, a Y-axial direction, a Z-axial direction, a theta rotational axial direction, an alpha rotational axial direction, and a beta rotational axial direction, similar to the piezo stages 20a, 20b described herein above.

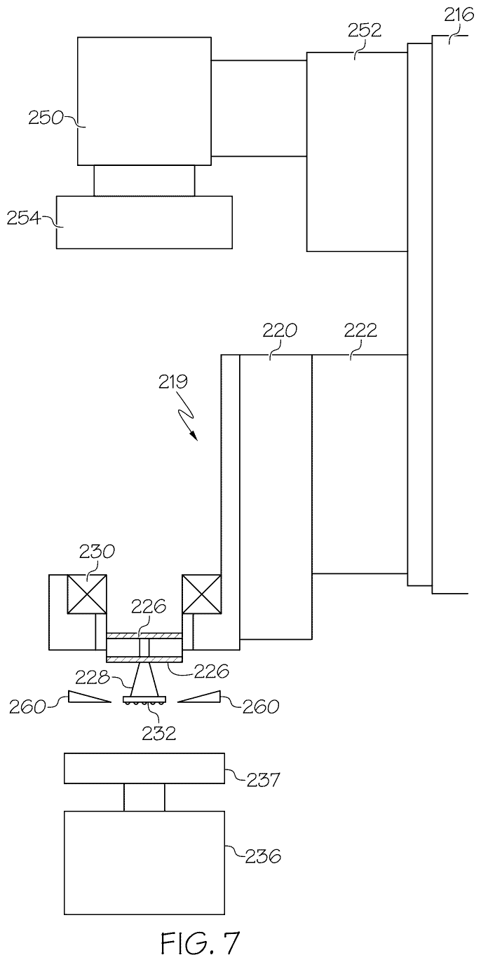

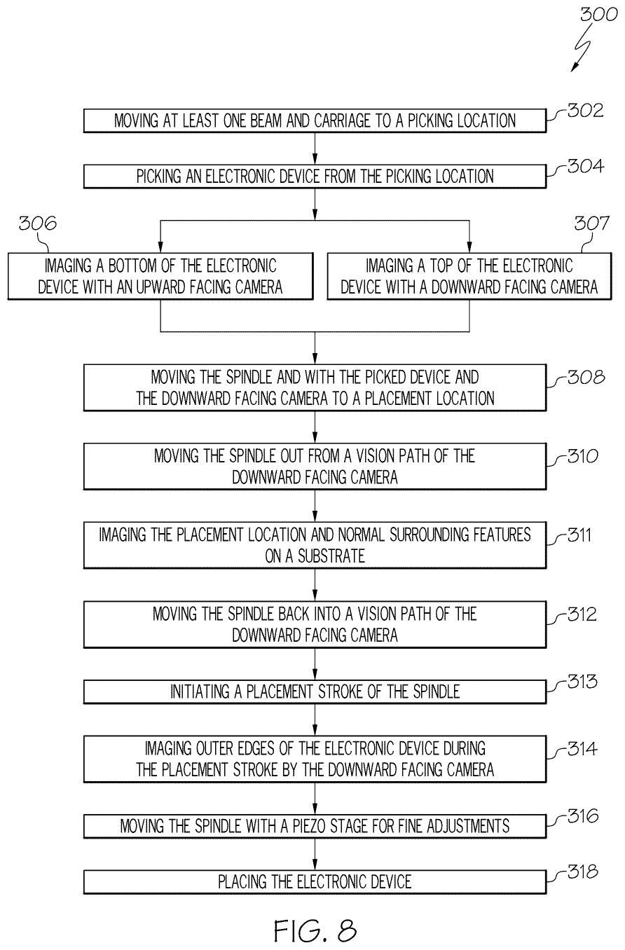

Referring now to FIG. 7, a side schematic view of the electronic device placement system 200 of FIGS. 6A and 6B including the downward facing camera 250 and the spindle 218 is shown located over an upward facing camera 236, according to one embodiment. The upward facing camera 236 may be a stationary camera, or alternatively may include its own positioning system. Whatever the embodiment, the upward facing camera 236 and the downward facing camera 250 may be positionable or movable so that they are vertically aligned such that the downward facing camera can capture the outline of a picked electronic component through the transparent spindle while the upward facing camera captures a bottom of the electronic component.

As shown, the upward facing camera 236 includes its own lens and/or lighting system 254. As shown in FIG. 7, the upward facing camera 254 may configured to image the bottom of the electronic device 232 concurrently with the imaging of a top of the device 232 by the downward facing camera 250. To accomplish this imaging, the upward facing lighting system 237 and the downward facing lighting system 254 may be configured for synchronized illumination during concurrent imaging of the upward facing camera and the downward facing camera of the electronic device. For example, this illumination may be a sub-10 microsecond illumination for imaging by both cameras to eliminate the impact of any vibrations of the system.

In some embodiments, an aperture 260 having a sharp inner edge may be located above the upward facing camera 236 such that the electronic device 232 is positionable at a height of the aperture 260 during the concurrent imaging of the upward facing camera 236 and the downward facing camera 250 of the electronic device 232. This aperture or blade may fully surround the electronic device 232 and may narrow to an extremely thin bladed point at its inner perimeter surrounding the component. This aperture 260 may help in the calibration or aligning of the imaging.

In the embodiment shown in FIGS. 6A-6B, the sequence of events may be as follows. First, the placement head system (i.e. the carriage 216 and the attached components) is moved by the positioning system in X and Y directions to the device feeder location (not shown) for pick-up of the electronic device 232. The downward facing camera 250 may be used for this move to ensure that the nozzle 228 picks the electronic device 232 such that there is an edge of the electronic device 232 that remains visible to the downward facing camera 250 beyond the entire perimeter of the tip of the spindle 218. Then, the positioning system moves the spindle 218 to an upward looking device camera which is configured to image the contact bumps of the electronic device in such a way that an exact target for X, Y and theta is found. Subsequently, the imaging and/or control system processes the same image for the edge of the electronic device 232 and calculates the relation between the edge and the X, Y and theta target. Next, the positioning system moves the spindle 218 to the placement site on the substrate 234 to within around 10 micron for X and Y, around 2 mm for Z, and around 0.01 degree for theta. By looking at the edge of the electronic device 232, the downward facing camera 250 may calculate the center of the bumps using the information provided by the upward facing camera. After moving the downward facing camera 250 down by around 2 mm, the downward facing camera 250 may image the substrate 234. In one embodiment, if a larger correction is required, the positioning system may further move the carriage 216. However, if the target is within microns, the piezo stage 220 may be used and the electronic device 232 is centered with precision to the target on the substrate 234. The spindle 218 is then lowered by the spindle assembly Z-drive 222 until, without touching, the device edge is in focus of the downward facing camera 250 at the same time as the substrate features are in focus. At this time a final correction may be needed by the piezo stage 220 to achieve nanometer alignment in X, Y, theta. Then, the placement is executed by the spindle assembly Z-drive 222 and/or the piezo stage 220. The piezo stage actuators can at this time be used as sensors to register the contact force. The alpha and beta axes from the piezo stage are used in combination with a set of laser sensors to adjust to the substrate surface angle in a way that all bumps make contact to their targets at the same time.

FIG. 7 depicts another method 300 of placing an electronic device, such as the electronic device 332a of FIGS. 6A and 6B, according to one embodiment. The method 300 includes a first step 302 of moving at least one beam and movably coupled carriage to a picking location. The step 302 may include moving the at least one beam with respect to at least one linear bearing along a Y-axis when the at least one beam is disposed along an X-axis that is perpendicular to the Y-axis and the at least one beam is movably coupled to the at least one linear bearing. The step 302 may further include moving the carriage with respect to the at least one along the X-axis, wherein the carriage is movably coupled to the at least one beam.

The method 300 may include a next step 304 of picking, by a nozzle of a spindle (e.g., a spindle which is coupled to a spindle assembly Z-drive as shown in FIGS. 6A and 6B), an electronic device at the picking location. The spindle may includes a transparent spindle body, and the nozzle may also be transparent and/or mounted vertically to the transparent spindle body.

The method 300 may then include a step 306 of moving the spindle with the picked electronic device to an imaging location and imaging, by a device camera facing upward, a bottom of the electronic device at the imaging location. Concurrent to the step 306 of imaging the bottom of the electronic device by the upward facing camera, the method 300 may include a simultaneous step 307 of imaging a top of the electronic device with the downward facing camera. This concurrent imaging may provide a high accuracy relation between the top edge imaged in step 307 of the electronic device and the bump pattern imaged during the step 306 of the bottom of the electronic device.

The method 300 may then include a step 308 of moving the spindle with the picked electronic device to a placement location by moving one or more of: the at least one beam along the Y-axis, the carriage along the X-axis, and the spindle assembly z-drive along the Z-axis; rotating the spindle and the nozzle with the theta drive. The step 308 may further include moving a downward facing camera facing downward above the placement location.

The method 300 then includes a step 310 of moving the spindle out from a vision path of the downward facing camera when the downward facing camera is pointed at the placement location. This may be accomplished, for example, by hingedly rotating the spindle about the carriage and/or moving the spindle along a spindle linear bearing with respect to the carriage. The method may then include a step 311 of imaging the placement location and normal surrounding features on a substrate. The method may then include a step 312 of moving the spindle back into a vision path of the downward facing camera.

The method 300 may then include a step 313 of initiating a placement stroke of the spindle to begin placing the picked electronic device on a substrate at the placement location. This step 313 may include moving a spindle assembly Z-drive with respect to the carriage along a Z-axis that is vertical and perpendicular to the X-axis and the Y-axis when the spindle assembly Z-drive is movably coupled to the carriage.

The method 300 includes a step 314 of imaging, by the downward facing camera, outer edges of the electronic device during the placement stroke of the spindle through the transparent spindle body. This may include moving a camera Z-drive with respect to the carriage along the Z-axis to move the downward facing camera along the Z-axis and/or independently moving the downward facing camera with respect to the carriage along the Z-axis relative to the spindle.

The method 300 may then include a step 316 of moving the spindle with respect to the spindle assembly Z-drive with a piezo stage to make fine adjustments to positioning of the spindle. For example, the step 316 may include making fine adjustments to positioning of the spindle, with the piezo stage, in 6 axial directions, including an X-axial direction, a Y-axial direction, a Z-axial direction, a theta rotational axial direction, an alpha rotational axial direction, and a beta rotational axial direction. A final step 318 of the method 300 may include placing the electronic device on the substrate.

The methods described herein may provide for placing the electronic device picked up by the nozzle of the spindle assemblies described with accuracy better than 1 micron. Moreover, the methods may include capturing, with the downward facing camera, a single image that contains an outline of the device and a surface of a substrate during the placement stroke whereby no fiducials or special marks are required on the substrate. Various other advantages may be achieved through application of the concepts provided herein.

One of the advantages of the above-described embodiments is improved placement accuracy, needed for the next generation of chip design. This is mainly achieved by the fact that steps have been eliminated in the placement process that contribute to the placement error. The present embodiments uniquely provide for a closed loop placement by processing a single image that contains the outline of the device and the surface of the substrate during the actual placement. Another major advantage over prior art equipment is the fact that no special marks of fiducials are required on the device or on the substrate. Rather, the present system may be implemented with only device known device features and substrate features. This saves significant money and creates smaller products.

Another advantage of the embodiments shown in FIGS. 1 and 2 is the use of two drive systems to achieve the improved accuracy. Unique about this placement process is the fact that the spindle-camera is on an independent positioning system from the placement head-positioning system. This allows parallel process and will increase the output of the system, especially when using two placement head-positioning systems on each side of the spindle-camera positioning system. This allows for the device pick and device-camera imaging to take place in parallel to the placement process, increasing (up to doubling) the system output.

Also unique for this mechanism is the moving of the downward facing camera in the Z-direction using the camera Z-drives described herein. This enables a true closed loop active alignment until the touch-down of the component.

The ability to image the outline of the device during the placement cycle may also be of value without the piezo stage, but only deploying a traditional X, Y, Z, and theta positioning system. In other words, embodiments are contemplated in which no piezo stage is deployed for fine adjustments. However, a piezo stage has been found to be a major improvement for placement in cases where there is no precision data on the location of the target on a printed circuit board (PCB) or substrate. In this case all the corrections can be made by a higher precision positioning system directly.

In various alternative embodiments, it may also be useful to make the glass plate spindle easily exchangeable on the placement head drive, for accommodating various other device sizes. Further, a glass plate spindle without a nozzle may be deployed as a tool to calibrate the upward facing camera(s) to the downward facing camera by placing a glass device on the upward facing camera and imaging this glass device with both cameras at the same time.

As previously described, instead of a glass plate, other transparent materials may be used especially if different wavelength light may be used for illumination, like infrared light or X-ray. Furthermore, instead of a separate nozzle mounted between the two glass plates protruding through the bottom plate, a glass plate with a salient glass protrusion may be used to reveal more of the top surface to the downward facing camera.

For the single-beam version shown in FIGS. 5A and 5B, the entire spindle assembly may be mounted on a hinge, or on a horizontal linear bearing in such a way that the spindle assembly can move out from the path of the downward facing camera path after picking or placing the device. This may allow the downward facing camera to view the substrate directly without the spindle located therebetween for the highest accuracy to image the substrate bumps and/or features directly and calculate the actual relationship between bumps and features of the electronic device and substrate before the placement process starts after the spindle assembly moves back in line with the Spindle-camera.

In another sequence of events, the theta drive of the spindles my rotate the spindle and thereby the electronic device as a first step in the placement sequence such that the downward facing camera can image the corners of the bump pattern on the substrate and calculate the relationship of this bump pattern to the visible features on the substrate which are visible to the downward facing camera during the placement process.

Elements of the embodiments have been introduced with either the articles “a” or “an.” The articles are intended to mean that there are one or more of the elements. The terms “including” and “having” and their derivatives are intended to be inclusive such that there may be additional elements other than the elements listed. The conjunction “or” when used with a list of at least two terms is intended to mean any term or combination of terms. The terms “first” and “second” are used to distinguish elements and are not used to denote a particular order.

While the invention has been described in detail in connection with only a limited number of embodiments, it should be readily understood that the invention is not limited to such disclosed embodiments. Rather, the invention can be modified to incorporate any number of variations, alterations, substitutions or equivalent arrangements not heretofore described, but which are commensurate with the spirit and scope of the invention. Additionally, while various embodiments of the invention have been described, it is to be understood that aspects of the invention may include only some of the described embodiments. Accordingly, the invention is not to be seen as limited by the foregoing description, but is only limited by the scope of the appended claims.

What is claimed is:

1. An electronic device placement system comprising:
a spindle assembly having a positioning system configured to move between a picking location and a placement location, the spindle assembly including a spindle having a transparent spindle body, the spindle including a nozzle mounted vertically to the transparent spindle body;
an upward facing camera configured to image a bottom of an electronic device picked up by the nozzle of the spindle prior to a placement stroke of the electronic device; and
a downward facing camera movable above the spindle during picking and placement of an electronic device by the spindle, wherein the downward facing camera is configured to image outer edges of the electronic device during the placement stroke of the spindle through the transparent spindle body, and wherein the downward facing camera is configured to capture an image of a surface of a substrate prior to and/or during the placement stroke.

2. The electronic device placement system of claim 1, wherein the upward facing camera is configured to image the bottom of the electronic device concurrently with the imaging of a top of the device by the downward facing camera.

3. The electronic device placement system of claim 2, wherein the upward facing camera includes an upward facing lighting system and wherein the downward facing camera includes a downward facing lighting system, wherein the upward facing lighting system and the downward facing lighting system are configured for synchronized illumination during concurrent imaging of the upward facing camera and the downward facing camera of the electronic device.

4. The electronic device placement system of claim 3, further comprising an aperture located above the upward facing camera such that the electronic device is positionable at a height of the aperture during the concurrent imaging of the upward facing camera and the downward facing camera of the electronic device.

5. The electronic device placement system of claim 1, wherein the spindle is configured to move out from a vision path of the downward facing camera when the downward facing camera is pointed at a placement location.

6. The electronic device placement system of claim 1, wherein the spindle assembly and the downward facing camera are attached to a carriage of the positioning system, and wherein the spindle is configured to movable with respect to the downward facing camera by at least one degree of freedom.

7. The electronic device placement system of claim 6, further comprising:
a camera Z-drive operably attached to the downward facing camera, the camera Z-drive movably coupled to the carriage and configured to move with respect to the carriage in a vertical direction,
wherein the spindle assembly includes a spindle assembly Z-drive movably coupled to the carriage configured to move the spindle assembly with respect to the carriage along the vertical direction, wherein the upward facing camera is independently movable with respect to the carriage in the Z-axis relative to the spindle assembly.

8. The electronic device placement system of claim 1, further comprising a spindle assembly Z-drive and a piezo stage movably coupled between the spindle assembly Z-drive and the spindle, the piezo stage configured to move the spindle with respect to the spindle assembly Z-drive to make fine positioning adjustments to the positioning of the spindle, wherein the piezo stage is configured to make fine adjustments to the positioning of the spindle in 6 axial directions, including an X-axial direction, a Y-axial direction, a Z-axial direction, a theta rotational axial direction, an alpha rotational axial direction, and a beta rotational axial direction.

9. The electronic device placement system of claim 1, wherein the transparent spindle body includes two glass plates, and wherein the spindle includes a theta drive to rotate the nozzle.

10. The electronic device placement system of claim 1, wherein the electronic device placement system is configured to place the electronic device picked up by the nozzle of the spindle with accuracy better than 1 micron, and wherein the downward facing camera is configured to capture a single image that contains an outline of the device and normal features on the surface of the substrate during the placement stroke whereby no fiducials or special marks are required on the substrate.

11. A method for placing an electronic device comprising:
moving a spindle assembly with a positioning system to a picking location, the spindle assembly including a spindle having a transparent spindle body, the spindle including a nozzle mounted vertically to the transparent spindle body;
picking up an electronic component with the spindle;
imaging, with an upward facing camera, a bottom of the electronic component picked up with the spindle prior to placement of the electronic component;
moving the spindle with the electronic component to a placement location; and
imaging, with a downward facing camera, a surface of a substrate prior to and/or during the placement stroke;
imaging, with the downward facing camera that is movable above the spindle, outer edges of the electronic device during the placement stroke of the spindle through the transparent spindle body.

12. The method of claim 11, further comprising imaging, with the upward facing camera, the bottom of the electronic device concurrently with imaging of a top of the device by the downward facing camera.

13. The method of claim 12, wherein the upward facing camera includes an upward facing lighting system and wherein the downward facing camera includes a downward facing lighting system, the method further comprising:
synchronously illuminating, with the upward facing lighting system and the downward facing lighting system, during concurrent imaging of the upward facing camera and the downward facing camera.

14. The method of claim 13, further comprising:
providing an aperture located above the upward facing camera; and
positioning the electronic device at a height of the aperture during the concurrent imaging of the upward facing camera and the downward facing camera of the electronic device.

15. The method of claim 11, further comprising moving the spindle out from a vision path of the downward facing camera when the downward facing camera is pointed at the placement location.

16. The method of claim 11, wherein the spindle assembly and the downward facing camera are attached to a carriage of the positioning system, and wherein the spindle is at least one of further comprising at least one of:
hingedly rotating the spindle about the carriage; and
moving the spindle along a spindle linear bearing with respect to the carriage.

17. The method of claim 16, wherein the positioning system further includes a camera Z-drive operably attached to the downward facing camera, and wherein the spindle assembly includes a spindle assembly Z-drive movably coupled to the carriage, the method further comprising:
moving, with the camera Z-drive, the camera in a vertical direction; and
moving, with the spindle assembly Z-drive, the spindle in the vertical direction, wherein the moving of the spindle assembly Z-drive is independent from the moving of the camera Z-drive.

18. The method of claim 11, wherein the spindle assembly further includes a spindle assembly Z-drive and a piezo stage movably coupled between the spindle assembly Z-drive and the spindle, the method further comprising:
moving the spindle with respect to the spindle assembly Z-drive with the piezo stage to make fine adjustments to positioning of the spindle, wherein the piezo stage is movably coupled between the spindle assembly Z-drive and the spindle; and
making fine adjustments to positioning of the spindle, with the piezo stage, in 6 axial directions, including an X-axial direction, a Y-axial direction, a Z-axial direction, a theta rotational axial direction, an alpha rotational axial direction, and a beta rotational axial direction.

19. The method of claim 10, wherein the transparent spindle body includes two glass plates, and wherein the spindle includes a theta drive to rotate the spindle and the nozzle, the method further comprising rotating the spindle and the nozzle with the theta drive.

20. The method of claim 11, further comprising:
placing the electronic device picked up by the nozzle of the spindle with accuracy better than 1 micron; and
capturing, with the downward facing camera, a single image that contains an outline of the device and normal features on the surface of the substrate during the placement stroke whereby no fiducials or special marks are required on the substrate.
